(19) United States
(12) Patent Application Publication
(10) Pub. No.: US 2024/0429674 A1
(43) Pub. Date: Dec. 26, 2024

(54) OPTOELECTRONIC CONVERTER ELEMENT, OPTOELECTRONIC SEMICONDUCTOR DEVICE AND METHOD FOR PRODUCING AN OPTOELECTRONIC COMPONENT

(71) Applicant: ams-OSRAM International GmbH, Regensburg (DE)

(72) Inventors: Zeljko PAJKIC, Regensburg (DE); Johann RAMCHEN, Hausen (DE)

(73) Assignee: ams-OSRAM International GmbH, Regensburg (DE)

(21) Appl. No.: 18/698,416

(22) PCT Filed: Sep. 29, 2022
(86) PCT No.: PCT/EP2022/077164

§ 371 Date: Apr. 4, 2024

(30) Foreign Application Priority Data
Oct. 8, 2021 (DE) 10 2021 126 160.0

(51) Int. Cl. H01S 5/00; H01L 25/075; H01L 33/00; H01L 33/50; H01S 5/42

(52) U.S. Cl. CPC H01S 5/0087; H01L 25/0753; H01L 33/005; H01L 33/502; H01L 33/505; H01S 5/42; H01L 2933/0041

(57) ABSTRACT

An optoelectronic converter element includes a substrate, which includes a material having a thermal conductivity of greater 25 W/(m*K), openings being formed in the substrate, and a luminophore located in the openings, thereby defining converter regions.

### CROSS-REFERENCE TO RELATED APPLICATIONS

The present application is a national stage entry from International Application No. PCT/EP2022/077164, filed on Sep. 29, 2022, published as International Publication No. WO 2023/057312 A1 on Apr. 13, 2023, and claims priority to German Patent Application No. 10 2021 126 160.0, filed Oct. 8, 2021, the disclosures of all of which are hereby incorporated by reference in their entireties.

### BACKGROUND

Surface-emitting semiconductor lasers or VCSELs (“Vertical Cavity Surface Emitting Lasers”) are increasingly being used for lighting purposes. Due to the higher luminance and energy densities that occur with surface-emitting lasers, it is necessary to develop new types of converter elements.

The present invention is based on the task of providing an improved optoelectronic converter element as well as an improved optoelectronic semiconductor component and an improved method for manufacturing an optoelectronic semiconductor component. According to embodiments, the problem is solved by the subject matter of the independent patent claims. Advantageous further developments are defined in the dependent patent claims.

### SUMMARY

An optoelectronic converter element comprises a carrier comprising a material having a thermal conductivity greater than 25 W/(m*K), wherein openings are formed in the carrier, and a phosphor disposed in the openings, thereby defining converter regions. According to further embodiments, the carrier may comprise a material having a thermal conductivity greater than 50 W/(m*K).

The optoelectronic converter element can also have a reflective layer between the carrier and the phosphor. Alternatively or additionally, the material of the carrier can be reflective.

The material of the carrier can be reflective and, for example, have a reflectivity for radiation converted by the converter element of at least 75%, at least 80% or at least 90% at an interface between the carrier and the phosphor.

The aforementioned optional reflective layer between the carrier and the phosphor may, for example, has a reflectivity for radiation converted by the converter element of at least 75%, at least 80% or at least 90%.

The thickness of the carrier can be larger than 5 μm. According to further embodiments, the thickness can also be larger than 10 μm.

For example, the converter areas can be arranged along rows and columns or according to a hexagonal pattern.

An optoelectronic semiconductor component comprises the optoelectronic converter element as described above and a semiconductor device for generating electromagnetic radiation. The optoelectronic converter element is configured to change a wavelength of electromagnetic radiation emitted by the semiconductor device.

For example, the semiconductor device may comprise a surface-emitting semiconductor laser element. According to further embodiments, the semiconductor device may also comprise a light-emitting diode (LED).

For example, the semiconductor device has an arrangement of light-emitting elements. The converter areas of the optoelectronic converter element are each arranged at positions that correspond to the positions of the light-emitting elements.

The optoelectronic semiconductor component may further include a solder frame between the semiconductor device and the optoelectronic converter element.

According to embodiments, an air gap can be arranged between the semiconductor device and the optoelectronic converter element.

For example, the optoelectronic semiconductor component can be selected from a broadband light source for spectroscopic applications, a flash light, a vehicle lighting device, a smartphone or a wearable electronic device.

A method of manufacturing a semiconductor optoelectronic device comprises forming openings in a carrier comprising a material having a thermal conductivity greater than 25 W/(m*K), introducing a phosphor into the openings thereby defining converter regions, and assembling the carrier with a semiconductor device for generating electromagnetic radiation. For example, the carrier can also have a material with a thermal conductivity greater than 50 W/(m*K).

For example, the converter areas are formed along rows and columns or according to a hexagonal pattern.

For example, the phosphor is introduced using a deposition process, screen printing, an immersion bath or casting.

According to embodiments, the method further comprises inserting a solder frame between the carrier and the semiconductor device.

For example, the semiconductor device can have a large number of light-emitting elements. The converter areas can each be arranged at positions corresponding to those of the light-emitting elements.

The accompanying drawings are intended to provide an understanding of embodiments of the invention. The drawings illustrate embodiments and, together with the description, serve to explain them. Further examples of embodiments and many of the intended advantages are directly apparent from the following detailed description. The elements and structures shown in the drawings are not necessarily shown to scale in relation to one another. Identical reference signs refer to identical or corresponding elements and structures.

### BRIEF DESCRIPTION OF THE DRAWINGS

FIG. 1A shows a schematic cross-sectional view of an optoelectronic converter element according to embodiments.

FIG. 1B shows a schematic cross-sectional view of an optoelectronic converter element according to further embodiments.

FIG. 2A shows a schematic cross-sectional view of an optoelectronic semiconductor component according to embodiments.

FIG. 2B illustrates the structure of an example of a surface-emitting semiconductor laser element.

FIG. 2C shows another example of a light-emitting element.

FIG. 3A shows a perspective view of a semiconductor device.

FIG. 3B shows a perspective view of an optoelectronic semiconductor component.

FIG. 4A shows a perspective view of a carrier for forming a converter element.

FIG. 4B shows a perspective view of the carrier with openings and converter areas.

FIG. 4C shows individual optoelectronic converter elements.

FIG. 5 illustrates a process for manufacturing an optoelectronic semiconductor component.

FIG. 6 summarizes a method according to embodiments.

### DETAILED DESCRIPTION

In the following detailed description, reference is made to the accompanying drawings, which form part of the disclosure and in which specific embodiments are shown for illustrative purposes. In this context, directional terminology such as “top”, “bottom”, “front”, “back”, “above”, “on”, “in front of”, “behind”, “front”, “rear”, etc. is referred to the orientation of the figures just described. Since the components of the embodiments can be positioned in different orientations, the directional terminology is for explanatory purposes only and is in no way limiting.

The description of the embodiments is not limiting, since other embodiments exist and structural or logical changes can be made without departing from the scope defined by the claims. In particular, elements of embodiments described below may be combined with elements of other described embodiments, unless the context indicates otherwise.

Depending on the intended use, semiconductor materials described below may be based on a direct or an indirect semiconductor material. Examples of semiconductor materials particularly suitable for generating electromagnetic radiation include, in particular, nitride semiconductor compounds which can be used to generate ultraviolet, blue or longer wavelength light, such as GaN, InGaN, AlN, AlGaN, AlGaInN, AlGaInBN, phosphide semiconductor compounds that can generate green or longer wavelength light, such as GaAsP, AlGaInP, GaP, AlGaP, as well as other semiconductor materials such as GaAs, AlGaAs, InGaAs, AlInGaAs, SiC, ZnSe, Zno, Ga 023, diamond, hexagonal BN and combinations of the aforementioned materials. The stoichiometric ratio of the compound semiconductor materials can vary. Other examples of semiconductor materials may include silicon, silicon-germanium and germanium. In the context of the present description, the term “semiconductor” also includes organic semiconductor materials.

The term “carrier” generally includes insulating, conductive or semiconductor carriers.

Typically, the wavelength of electromagnetic radiation emitted by an LED chip can be converted using a converter material containing a phosphor or phosphor. For example, white light can be generated by combining an LED chip that emits blue light with a suitable phosphor. For example, the phosphor may be a yellow phosphor which, when excited by the light from the blue LED chip, is capable of emitting yellow light. The phosphor can, for example, absorb some of the electromagnetic radiation emitted by the LED chip. The combination of blue and yellow light is perceived as white light. The color temperature can be changed by adding other phosphors that are suitable for emitting light of another wavelength, for example a red wavelength. According to further concepts, white light can be generated by a combination containing a blue LED chip and a green and red phosphor. It goes without saying that a converter material can comprise several different phosphors, each emitting different wavelengths.

Examples of phosphors are metal oxides, metal halides, metal sulphides, metal nitrides and others. These compounds can also contain additives that cause special wavelengths to be emitted. For example, the additives may include rare earth materials. As an example of a yellow phosphor, YAG: Ce³⁺ (yttrium aluminum garnet activated with cerium (Y₃Al₅O₁₂)) or (Sr_{1.7}Ba_{0.2}Eu_{0.1})SiO₄ can be used. Other phosphors can be based on MSiO₄: Eu²⁺, where M can be Ca, Sr or Ba. By selecting the cations with an appropriate concentration, a desired conversion wavelength can be selected. Many other examples of suitable phosphors are known.

According to applications, the phosphor material, for example a phosphor powder, may be embedded in a suitable matrix material. For example, the matrix material may comprise a resin or polymer composition such as a silicone or epoxy resin. The size of the phosphor particles can be in the micrometer or nanometer range, for example.

According to further embodiments, the matrix material may comprise a glass. For example, the converter material can be formed by sintering the glass, for example SiO₂ with further additives and phosphor powder, forming a phosphor in the glass (PiG).

According to further embodiments, the phosphor material itself can be sintered to form a ceramic. For example, as a result of the sintering process, the ceramic phosphor can have a polycrystalline structure.

According to further embodiments, the phosphor material can be grown to form a monocrystalline phosphor, for example using the Czochralski (Cz-) process.

According to further embodiments, the phosphor material itself can be a semiconductor material that has a suitable band gap in the volume or in layers for absorbing the light emitted by the LED and for emitting the desired conversion wavelength. In particular, this can be an epitaxially grown semiconductor material. For example, the epitaxially grown semiconductor material can have a band gap that corresponds to a lower energy than that of the primary emitted light. Furthermore, several suitable semiconductor layers, each emitting light of a different wavelength, can be stacked on top of each other. One or more quantum wells or quantum wells, quantum dots or quantum wires can be formed in the semiconductor material.

The term “vertical” as used in this description is intended to describe an orientation that is substantially perpendicular to the first surface of a carrier or semiconductor body. The vertical direction may, for example, correspond to a growth direction during the growth of layers.

The terms “lateral” and “horizontal”, as used in this description, are intended to describe an orientation or alignment that is substantially parallel to a first surface of a carrier or semiconductor body. This can be, for example, the surface of a wafer or a die.

The horizontal direction can, for example, lie in a plane perpendicular to a growth direction when layers are growing.

In the context of this description, the term “electrically connected” means a low-resistance electrical connection between the connected elements. The electrically connected elements do not necessarily have to be directly connected to each other. Other elements can be arranged between electrically connected elements.

The term “electrically connected” also includes tunnel contacts between the connected elements.

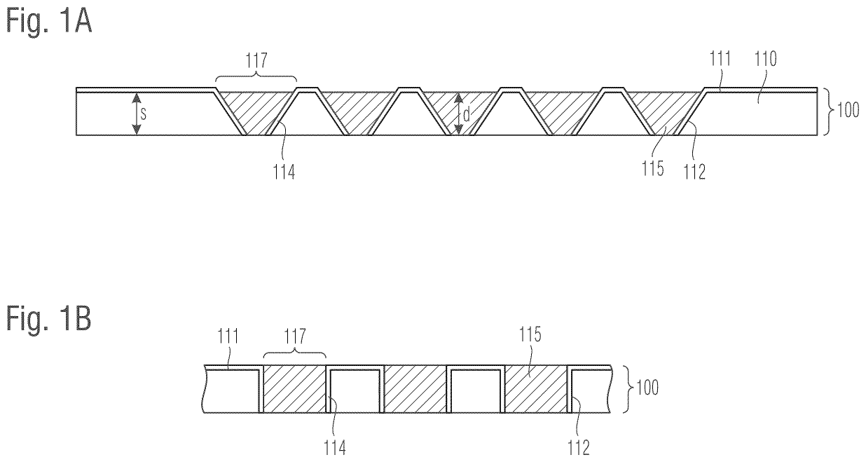

FIG. 1A shows a schematic cross-sectional view of an optoelectronic converter element 100 according to embodiments. The optoelectronic converter element 100 comprises a carrier 110 having a carrier material with a thermal conductivity greater than 50 W/(m*K). Openings 112 are formed in the carrier 110. The openings 112 extend from a first main surface 111 of the carrier 110 to a surface of the carrier 110 opposite the first main surface 111. A phosphor 115 is arranged in the openings 112. This defines converter regions 117. The phosphor 115 extends within the converter regions 117 from the first main surface 111 to the surface of the carrier 110 opposite the first main surface 111.

Examples of the carrier material include metals such as Cu, Al, Ag, Au, metal alloys and ceramics such as AIN, Al₂O₃, TiO₂, diamond or SiC. Further examples of the material of the carrier include carbon or other composite materials. According to further embodiments, other materials with a high thermal conductivity can also be used.

The thermal conductivity of the carrier material can, for example, be greater than 50 or greater than 100 W/(m*K). The openings 112 may, for example, be conical, so that the diameter of the openings 112 on the side facing the light-emitting elements (not shown in FIG. 1A) is smaller than the diameter of the openings 112 on a side facing away from the light-emitting elements.

The phosphor may be embedded in a matrix material, for example a polymer or a glass. According to embodiments, a reflective layer 114 having a high reflectivity may be disposed between the carrier 110 and the phosphor 115. For example, the reflective layer 114 may be disposed on the sidewalls of the openings 113 and over the first major surface 111 of the carrier 110. The reflective layer may include or consist of Au or Ag, for example. In this way, back reflection of generated radiation towards the semiconductor device is reduced and the overall light output can be increased. Furthermore, heating of the converter element is reduced. For example, a layer thickness of the carrier 100 can be greater than 10 um. For example, a layer thickness of the carrier 100 can be less than 100 um. In general, a layer thickness of the phosphor 115 in the openings may be approximately equal to the layer thickness of the carrier 100. More precisely, 0.9*s≤d≤1.1*s, where d denotes the layer thickness of the phosphor 115 and s denotes the layer thickness of the carrier 100.

FIG. 1B shows a cross-sectional view of the optoelectronic converter element 100 according to further embodiments. As can be seen, the openings are cylindrical here-unlike those shown in FIG. 1A. The other elements of the optoelectronic converter element correspond to those shown in FIG. 1A. Here too, the reflective layer 114 is optional and can be omitted.

Due to the special design of the optoelectronic converter element 100, heat generated in the individual converter areas 117 can be dissipated particularly efficiently. As a result, negative effects associated with heating of the converter element are avoided or suppressed. In particular, damage to the converter element can be avoided, thereby increasing its service life.

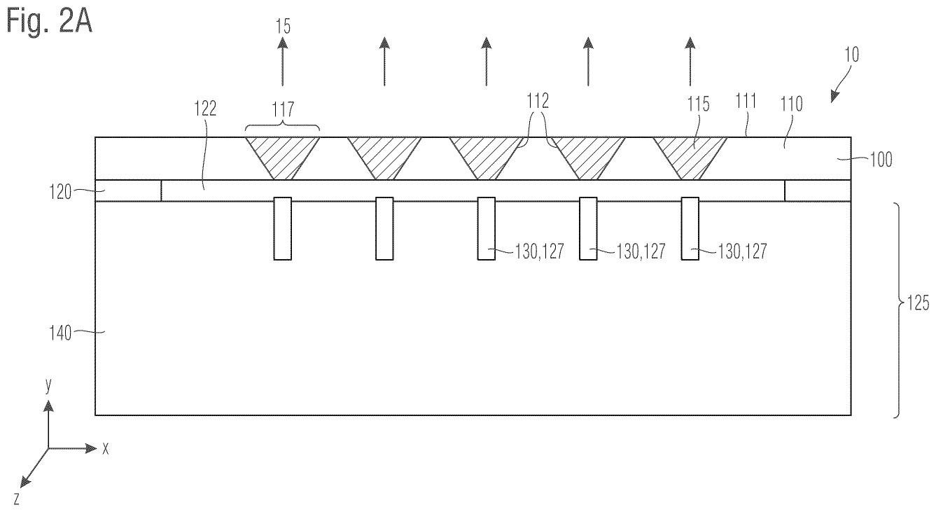

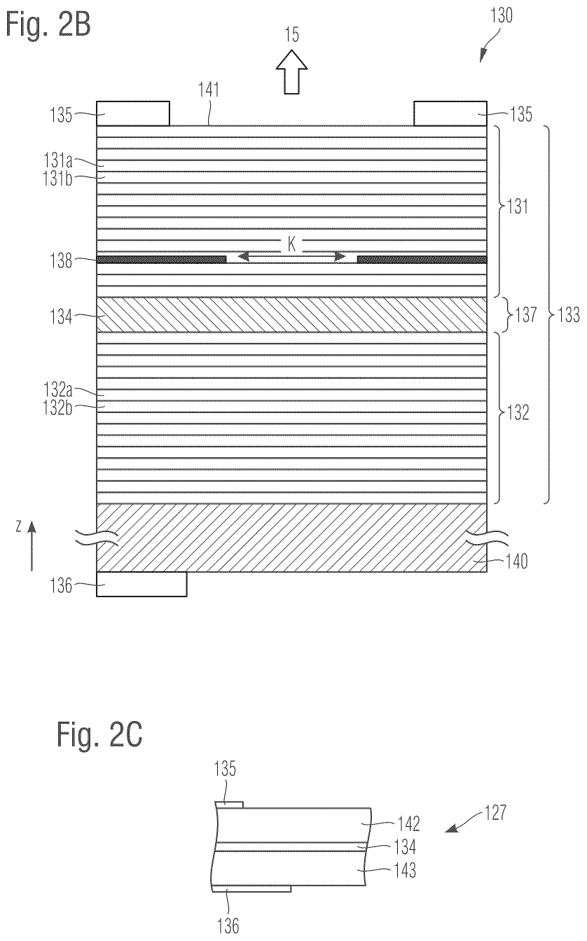

FIG. 2A shows a schematic cross-sectional view of an optoelectronic semiconductor component 10 according to embodiments. The optoelectronic semiconductor component 10 comprises an optoelectronic converter element 100 and a semiconductor device 125 for generating electromagnetic radiation. The optoelectronic converter element 100 may be configured as described above. The optoelectronic converter element 100 is configured to change a wavelength of emitted electromagnetic radiation 15 emitted from the semiconductor device.

For example, the semiconductor device 125 may comprise a surface emitting laser element 130. According to embodiments, the semiconductor device may comprise a plurality of light emitting elements 127. For example, these light emitting elements 127 may be surface emitting semiconductor laser elements 130. According to further embodiments, however, the light-emitting elements 127 may also be designed in a different manner.

When a plurality of light emitting elements 127 are used, the converter regions 117 of the optoelectronic converter element 100 may be arranged in positions corresponding to the positions of the light emitting elements 127. In this way, electromagnetic radiation 15 that has been emitted from the individual light emitting elements 127 can be converted directly by an associated converter region 117. In this way, phosphor material can be saved, thereby reducing the cost of the optoelectronic semiconductor component.

For example, the individual light emitting elements 127 may be arranged in or over a carrier 140. According to embodiments, a solder frame may be disposed between the carrier 140 and the converter element 100. In this way, a predetermined distance between the emission surface of the light emitting element 127 and the converter regions 117 may be provided. The solder frame 120 may be disposed in an edge region of the semiconductor device 125. For example, an air gap is disposed between the emission surface and the converter region 117. The air gap has a different refractive index and thus leads to improved beam shaping. The air gap is arranged, for example, in an area that is different from the edge area of the semiconductor device and the converter element 100.

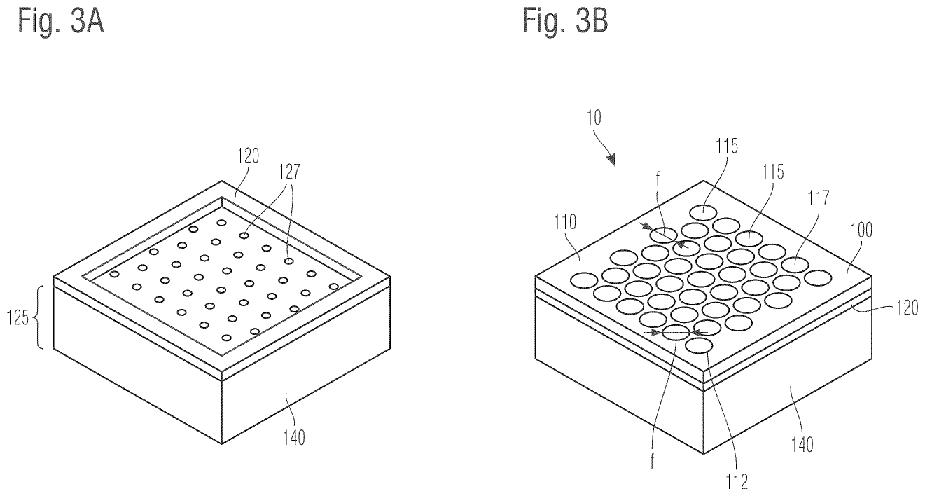

For example, a material of the solder frame 120 may comprise Au or an alloy comprising Cu, Ni and/or Au as well as other suitable materials. For example, a thickness of the solder frame 120 measured in the y-direction may be greater than 2 μm. According to further embodiments, the thickness of the solder frame 120 may be less than 10 um. Arrangement patterns in which both the light emitting elements 127 and the converter regions 117 may be arranged in the x-z plane will be described in more detail below with reference to FIGS. 3A and 3B.

FIG. 2B shows an example of a structure of a surface emitting semiconductor laser element 130, which according to embodiments may represent a light emitting element 127 shown in FIG. 2A. The surface emitting semiconductor laser element 130 comprises a first resonator mirror 131 and a second resonator mirror 132, as well as an active zone 134 for generating radiation. The active zone may, for example, have a p-n junction, a double heterostructure, a single quantum well (SQW) structure or a multiquantum well (MQW) structure for generating radiation. The term “quantum well structure” has no meaning with regard to the dimensionality of the quantization. It therefore includes quantum wells, quantum wires and quantum dots as well as any combination of these layers.

The first resonator mirror 131 and the second resonator mirror 132 can each be formed as a DBR (“distributed bragg reflector”) layer stack and have a plurality of alternating thin layers of different refractive indices. The thin layers may each be constructed of a semiconductor material or a dielectric material. For example, the layers can alternately have a high refractive index (n>specified refractive index) and a low refractive index (n<specified refractive index). For example, the layer thickness can be λ/4 or a multiple of λ/4,where λ indicates the wavelength of the light to be reflected in the corresponding medium. The first or second resonator mirror can, for example, have 2 to 50 individual layers. A typical layer thickness of the individual layers can be approximately 30 to 150 nm, for example 50 nm. The layer stack may also contain one or two or more layers that are thicker than about 180 nm, for example thicker than 200 nm. Accordingly, an optical resonator 137 is formed between the first and second resonator mirrors 131, 132.

When the first resonator mirror 131 is constructed only of dielectric layers, the semiconductor layer stack 123 further comprises a first semiconductor layer of a first conductivity type, for example p-type, disposed adjacent to the active region 134. When the second resonator mirror 132 is constructed only of dielectric layers, the semiconductor layer stack 123 further comprises a second semiconductor layer of a second conductivity type formed in contact with the active region 134. The surface emitting semiconductor laser element 130 further comprises a first contact element 135 and a second contact element 136 for applying a voltage to the laser element. In FIG. 2B, the first and second contact elements 135, 136 are arranged on opposite sides of the semiconductor layer stack 133. According to further embodiments, the first and second contact elements 135, 136 may be arranged on one side of the surface emitting semiconductor laser element 130, for example on the side of the carrier 140. In this way, shadowing effects due to the contact elements 135, 136 are avoided. The surface-emitting semiconductor laser element 130 may further comprise an aperture 138 for constricting and limiting the current flow to the central region of the surface-emitting semiconductor laser element 130. A diameter k of the aperture 138 may be greater than 6 μm. The diameter k of the aperture 138 can be smaller than 20 μm.

According to further embodiments, the light-emitting element 127 can also be designed in a different way. FIG. 2C shows a further example of a light emitting element 127, which is designed as a light emitting diode (LED). The light-emitting diode has a first semiconductor layer 142 of a first conductivity type, for example p-type, and a second semiconductor layer of a second conductivity type, for example n-type. An active region 134 is disposed between the first semiconductor layer 142 and the second semiconductor layer 143. The light-emitting element 127 further comprises a first contact element 135 and a second contact element 136 for applying a voltage to the light-emitting element 127.

FIG. 3A shows an example of a perspective view of a semiconductor device 125 with a solder frame 120 applied thereover. The semiconductor device 125 comprises a carrier 140 and a plurality of light emitting elements 127, which may be arranged according to a predetermined pattern, for example in rows and columns or, for example, in a hexagonal pattern.

FIG. 3B shows a perspective view of an optoelectronic semiconductor component 10 according to embodiments. For example, the optoelectronic semiconductor component 10 may comprise a combination of the semiconductor device 125 shown in FIG. 3A and the previously described optoelectronic converter element 100. The individual converter regions 117 may be arranged in a pattern corresponding to the pattern formed by the individual light emitting elements 127. For example, the converter regions 117 may be arranged in a hexagonal pattern or in rows or in columns. If the arrangement pattern of the converter areas 117 corresponds to the arrangement pattern of the light-emitting elements 127, converter areas 117 are present at the points at which electromagnetic radiation is incident on the optoelectronic converter element 100. Accordingly, phosphor can be saved.

As can be seen in FIG. 3B, the openings 112 can have a round cross-section in the x-z plane. According to further embodiments, the diameter of the opening 112 may also be hexagonal or polygonal. According to embodiments, the cross-section of the openings 112 is configured to the shape of the aperture 138 of the surface-emitting semiconductor laser elements 130. The phosphor 115 is arranged in each of the openings 112 formed in the carrier 110. For example, a diameter f of the openings 112 measured in the x-z plane is larger than the diameter k of the aperture 138 of the surface emitting semiconductor laser elements 130. In this way, optical losses can be minimized. For example, the diameter f of the openings 112 may be greater than 1.5 times or greater than 2 times the diameter k of the aperture 138. If the openings 112 are conical as shown in FIG. 2A, the diameter f of the openings 112 on the side facing the light-emitting elements 127 may be approximately equal to the diameter k of the apertures 138 of the light-emitting elements 127. On the side facing away from the light-emitting elements 127, the diameter f of the openings 112 may be larger than the diameter k of the apertures 138 of the light-emitting elements 127.

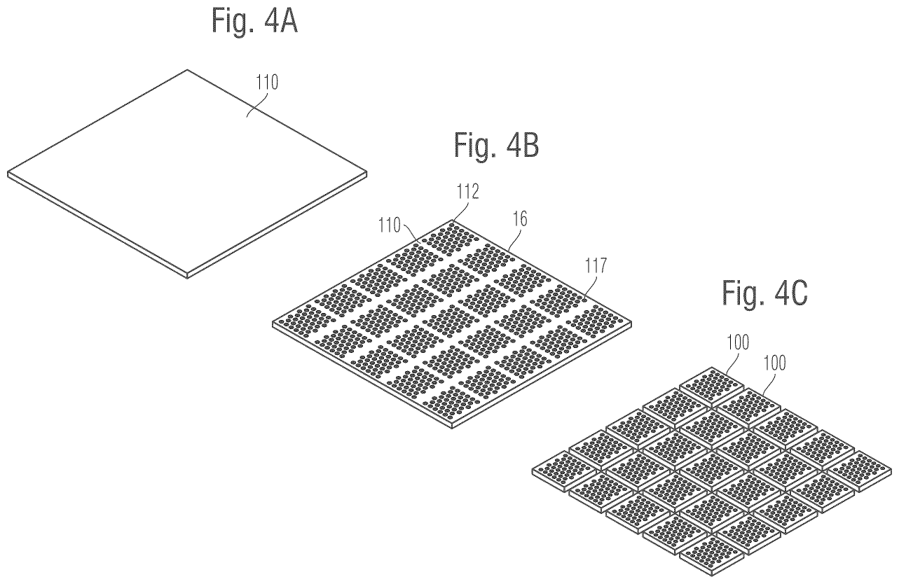

FIGS. 4A to 4C illustrate steps for manufacturing the described optoelectronic converter element. The starting point can be, for example, the carrier shown in FIG. 4A. Although a rectangular shape of the carrier 110 is shown in FIG. 4A, it is obvious that the carrier 110 may have the shape of a wafer or a wafer part, for example. For example, the carrier may include or be made of one of the aforementioned carrier materials. Openings 112 are then formed in the carrier 110 shown in FIG. 4A as described above. This can be done, for example, by laser drilling or by etching, for example in conjunction with a lithographic process.

FIG. 4B shows an example of a resulting workpiece 16. Subsequently, a highly reflective material may optionally be applied to form the reflective layer 114 as described above. For example, when the converted radiation is visible light or IR radiation, Ag may be used as the material of the reflective layer 114. According to further embodiments, when the converted radiation is IR radiation, Au may be used as the material of the reflective layer 114. Subsequently, the phosphor 115 is introduced into the individual openings 112. This can be done, for example, by deposition processes, screen printing processes, an immersion bath, casting or otherwise. Optionally, the resulting workpiece 16 can then be ground back or planarized. According to embodiments, separation can then be carried out, whereby individual optoelectronic converter elements 100 are obtained. This is illustrated schematically in FIG. 4C.

To produce an optoelectronic semiconductor component, either the separated individual converter elements 100 or the composite of several converter elements, which is present before separation, are subsequently applied over an arrangement of light-emitting elements 127. For example, the joining can be carried out via wafer bonding processes, for example using tin or an Au/Sn alloy. A solder frame 120 as described above may be previously deposited on the array of light emitting elements 127.

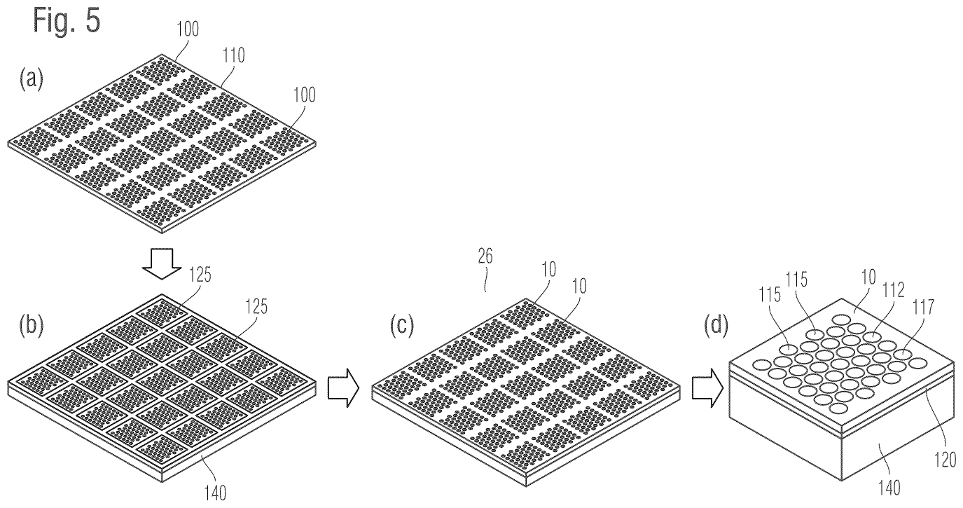

FIG. 5(a) shows an array of optoelectronic converter elements 100. FIG. 5(b) shows an array of semiconductor devices 125, each having an array of light emitting elements 127. The array of semiconductor devices is disposed over a carrier 140. After assembling the composite of converter elements 100 with the composite of semiconductor devices 125, the workpiece 26 shown in FIG. 5(c) is obtained. The joining may include, for example, a wafer bonding process, for example by Sn/AuSn.

The resulting workpiece 26 has, for example, a large number of optoelectronic semiconductor components 10. The workpiece can then be separated into individual optoelectronic semiconductor components 10 by sawing, as shown in FIG. 5(d). The optoelectronic semiconductor components 10 are thus manufactured using CSP (“chip size package”) technology. The optoelectronic semiconductor components 10 therefore have the size of a semiconductor chip. As a result, a high degree of miniaturization of the optoelectronic semiconductor components is achieved.

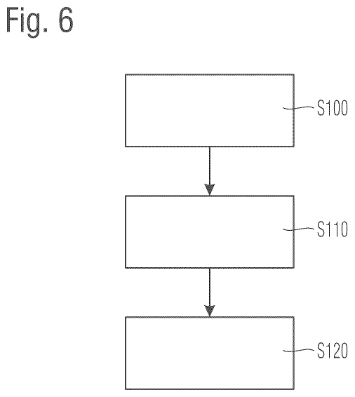

FIG. 6 summarizes a method according to embodiments. A method of manufacturing a semiconductor optoelectronic device comprises forming (S100) openings in a carrier comprising a material having a thermal conductivity greater than 50 W/(m*K), introducing (S110) a phosphor into the openings thereby defining converter regions, and assembling (S120) the carrier with a semiconductor device for generating electromagnetic radiation.

As has been described, the present invention provides an optoelectronic converter element 100 by which, on the one hand, the wavelength of the electromagnetic radiation emitted from the optoelectronic semiconductor component can be converted. Due to the special structure of the optoelectronic converter element 100 with a carrier 100 which is made of a material with a high thermal conductivity, heating of the converter can be effectively reduced. As a result, it is possible to operate the semiconductor device at higher currents and thus higher powers and luminance levels without any degradation of the optoelectronic semiconductor component due to heat generation. This extends the service life of the converter and also of the optoelectronic semiconductor component. Due to this mode of operation, the optoelectronic converter element is very effective, particularly in conjunction with a surface-emitting laser element. Areas of application for the optoelectronic semiconductor components 10, which have the semiconductor device and the optoelectronic converter element, include lighting devices with high luminance, for example for special applications, broadband light sources for spectrometry, flash light for smartphones, which has very high luminous fluxes, or for professional cameras. Another area of application is lighting in the automotive sector. Due to the special design of the converter element described, the optoelectronic semiconductor component can also be made very compact. A further area of application is so-called wearables or portable electronic devices such as smart watches, tracking bracelets or fitness bracelets. Such devices have a sensor and a light source, for example. The sensor can, for example, monitor a user's vital functions. If the light source is designed, for example, as an optoelectronic component as described above or with the converter element described here, heating of the device and thus impairment of its performance can be avoided.

Although specific embodiments have been illustrated and described herein, those skilled in the art will recognize that the specific embodiments shown and described may be replaced by a variety of alternative and/or equivalent embodiments without departing from the scope of protection of the invention. The application is intended to cover any adaptations or variations of the specific embodiments discussed herein. Therefore, the invention is limited only by the claims and their equivalents.

1. (canceled)

2. The optoelectronic semiconductor component according to claim 4, wherein a thickness of the carrier is larger than 5 μm.

3. (canceled) The optoelectronic semiconductor component according to claim 4, wherein the converter regions are arranged along rows and columns or according to a hexagonal pattern.

4. An optoelectronic semiconductor component comprising:
an optoelectronic converter element with,
a carrier comprising a material having a thermal conductivity greater than 25 W/(m*K), wherein openings are formed in the carrier, extending from a first main surface of the carrier to a surface of the carrier opposite the first main surface, and
a phosphor arranged in the openings, thereby defining converter regions, wherein the material of the carrier is reflective or the optoelectronic converter element further comprises a reflective layer between the carrier and the phosphor; and
a semiconductor device for generating electromagnetic radiation, and
a solder frame between the semiconductor device and the optoelectronic converter element,
wherein the optoelectronic converter element is configured to change a wavelength of electromagnetic radiation emitted from the semiconductor device.

5. The optoelectronic semiconductor component according to claim 4, wherein the semiconductor device comprises a surface emitting semiconductor laser element .

6. The optoelectronic semiconductor component according to claim 4, wherein the semiconductor device comprises a light emitting diode.

7. The optoelectronic semiconductor component according to 4, wherein the semiconductor device comprises an array of light-emitting elements, and the converter regions of the optoelectronic converter element are respectively arranged at positions corresponding to the positions of the light-emitting elements.

8. (canceled)

9. The optoelectronic semiconductor component according to claim 4, further comprising an air gap between the semiconductor device and the optoelectronic converter element.

10. The optoelectronic semiconductor component (10) according to claims 4, which is selected from a broadband light source for spectroscopic applications, a flash light, an automotive lighting device, a smartphone and a wearable electronic device.

11. A method of manufacturing an optoelectronic semiconductor component, comprising:
forming openings in a carrier comprising a material having a thermal conductivity greater than 25 W/(m*K),
Introducing introducing a phosphor into the openings, thereby defining converter regions; and
Assembling assembling the carrier with a semiconductor device for generating electromagnetic radiation,
wherein the material of the carrier is reflective or the method further comprises applying a reflective layer before introducing the phosphor.

12. The method according to claim 11, wherein the converter regions are formed along rows and columns or according to a hexagonal pattern.

13. The method according to claim 11, wherein the phosphor is introduced by a deposition process, a screen printing process, an immersion bath or casting.

14. The method according to 11, further comprising inserting a solder frame between the carrier and the semiconductor device.

15. The method according to claims 11, wherein the semiconductor device comprises a plurality of light-emitting elements, and the converter regions are respectively arranged at positions corresponding to those of the light-emitting elements.
